(19) United States
(12) Patent Application Publication
(10) Pub. No.: US 2024/0345180 A1
(43) Pub. Date: Oct. 17, 2024

(54) SYSTEM AND METHOD FOR DETERMINING CABLE PERFORMANCE BASED ON FREQUENCY DEPENDENT SKEW

(71) Applicant: Cisco Technology, Inc., San Jose, CA (US)

(72) Inventors: David Nozadze, San Jose, CA (US); Mike Sapozhnikov, San Jose, CA (US); Upen Reddy Kareti, Union City, CA (US); Amendra Koul, San Francisco, CA (US); Joel Richard Goergen, Soulsbyville, CA (US)

(21) Appl. No.: 18/422,854

(22) Filed: Jan. 25, 2024

Related U.S. Application Data
(60) Provisional application No. 63/495,679, filed on Apr. 12, 2023.

(51) Int. Cl. G01R 31/58; G01R 23/02

(52) U.S. Cl. CPC G01R 31/58; G01R 23/02

(57) ABSTRACT

Presented herein is a method comprising: determining skew values of cables, each skew value indicating a time of signal propagation along a respective cable at a respective signal frequency value, and the skew values being frequency dependent and varying at signal frequency values; determining skew behavior property values for each cable based on the skew values; determining a performance metric value for each skew behavior property value; determining a relationship between the skew values and the signal frequency values at each performance metric value based on the performance metric value for each skew behavior property value; and coupling a first electronic component and a second electronic component to one another using a new cable based on the relationship between the skew values and the signal frequency values at each performance metric value.

### CROSS-REFERENCE TO RELATED APPLICATIONS

This application claims priority to and the benefit of U.S. Provisional Patent Application No. 63/495,679, entitled “ANALYSIS OF FREQUENCY DEPENDENT INTRA-PAIR SKEW AND ITS IMPACT ON HIGH SPEED SERDES PERFORMANCE,” filed Apr. 12, 2023, and hereby incorporated by reference in its entirety for all purposes.

### TECHNICAL FIELD

The present disclosure relates to cables used to propagate signals.

### BACKGROUND

Cables may be used to couple electronic components to one another and propagate signals between the electronic components. For example, signals (e.g., differential signals that include a positive signal and a negative signal) may be transmitted along the cable for receipt by one of the electronic components. The electronic component may then operate based on the received signals. For example, differential pair twinax flyover cables may be used to obtain and provide signals to and from a printed circuit board (PCB) in serializer/deserializer (Serdes) applications. Travel of differential signals along a cable may vary. For example, a time of propagation of each signal along the cable may depend on a characteristic, such as a structure, of the cable. The varying times of propagation of the signals along the cable may cause skew, which is an aberration in signal (e.g., receipt of signals) caused by unequal propagation delays on each of the propagation mediums. Skew may affect different performance operations. Thus, it may be desirable to evaluate performance based on skew caused by the cables.

### BRIEF DESCRIPTION OF THE DRAWINGS

FIG. 1 is a side cross-sectional view of an electronic assembly that utilizes a cable, according to an example embodiment.

FIG. 2 is a schematic diagram of a manufacturing system used to test cable performance, according to an example embodiment.

FIGS. 3A and 3B are graphical plots of skew-related properties for a skew profile, according to an example embodiment.

FIGS. 4A and 4B are graphical plots of skew-related properties for another skew profile, according to an example embodiment.

FIGS. 5A and 5B are graphical plots of skew-related properties for yet another skew profile, according to an example embodiment.

FIGS. 6 and 7 are graphical plots of skew masks for different skew profiles, according to an example embodiment.

FIG. 8 illustrates tables of skew masks for different skew profiles, according to an example embodiment.

FIGS. 9 and 10 are flowcharts of methods for testing cables in relation with skew, according to an example embodiment.

FIG. 11 is a hardware block diagram of a computing or communication device that may perform functions associated with any combination of operations in connection with the techniques depicted and described herein, according to an example embodiment.

### DESCRIPTION OF EXAMPLE EMBODIMENTS

### Overview

Techniques are related to a method comprising: determining a plurality of skew values of a plurality of cables, wherein each skew value of the plurality of skew values indicates a time of signal propagation along a respective cable of the plurality of cables at a respective signal frequency value of a plurality of signal frequency values, and the plurality of skew values are frequency dependent and vary at the plurality of signal frequency values; determining a plurality of skew behavior property values for each cable of the plurality of cables based on the plurality of skew values; determining a performance metric value for each skew behavior property value of the plurality of skew behavior property values to generate a plurality of performance metric values; determining a relationship between the plurality of skew values and the plurality of signal frequency values at each performance metric value of the plurality of performance metric values based on the performance metric value for each skew behavior property value; and coupling a first electronic component and a second electronic component to one another using a new cable, separate from the plurality of cables, based on the relationship between the plurality of skew values and the plurality of signal frequency values at each performance metric value.

Cables may be used to transmit signals between electronic components. However, different cables can cause signals to travel at different speeds. Thus, signals propagated along the cables can have varying travel times to cause skew, such as between related signals (e.g., a positive signal, a negative signal) propagated by a differential pair. Skew can deteriorate or limit desirable performance, especially for high-speed serial-communication links. Indeed, demand for higher data rates are increasing, and allowable skew is correspondingly becoming more stringent to achieve desirable performance for the higher data rates. For this reason, to achieve a desirable performance, such as to enable a particular data rate (e.g., 224 gigabytes per second (Gbps)), the cables being used to transmit signals should limit skew to an acceptable amount. Increasing the complexity of skew is the fact that skew may be frequency dependent and can vary at different signal frequencies. Therefore, each cable and its varying skews can provide different performances at the different signal frequencies. As such, it is important to test cables and their skews at different signal frequencies to establish criteria for implementing the cables to provide desirable performances.

Embodiments discussed herein are directed to modeling skew to create threshold skews or skew masks that provide a boundary indicating permitted skew values at various signal frequencies to achieve a desirable performance for a particular application, then using the threshold skew curves to determine whether a cable is usable for a particular application, such as for inclusion in a Serdes processing device. That is, a methodology to model performance with respect to skew, as well as selecting or manufacturing an appropriate cable based on its skew, is provided. The methodologies discussed herein may be based on skew profiles with differing properties, such as causal scattering parameters and loss values, to provide more suitable performance evaluations.

### EXAMPLE EMBODIMENTS

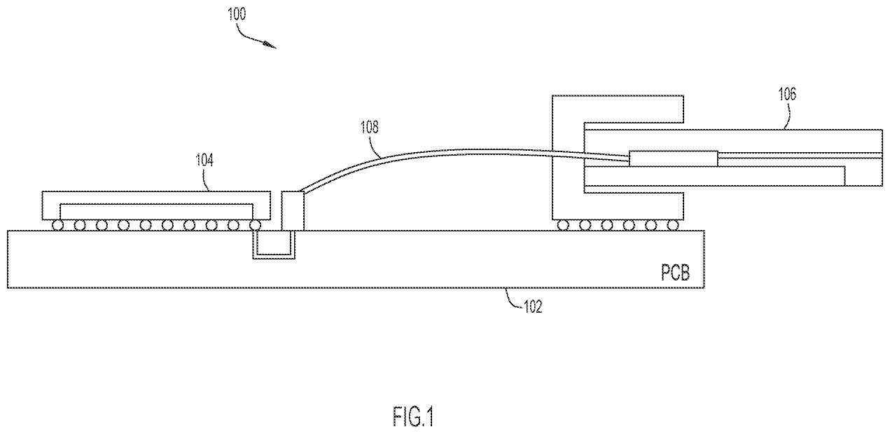

With reference to FIG. 1, depicted therein is a cross-sectional view of an electronic system 100 that includes a printed circuit board (PCB) 102 with a circuit 104 (e.g., an application-specific integrated circuit) and a module 106 (e.g., a network module) coupled thereto. A cable 108 may be used to couple the circuit 104 and the module 106 to one another to transmit signals (e.g., electronic signals) between the circuit 104 and the module 106. For example, the cable 108 may transmit signals from the module 106 to the circuit 104 and/or from the circuit 104 to the module 106. In either case, the PCB 102, the circuit 104, and/or the module 106 may operate based on the signals transmitted by the cable 108. In some embodiments, the cables 108 may include a differential pair of conductors configured to transmit a positive signal and a negative signal.

However, respective signals may travel at different speeds along the cable 108. For this reason, skew (e.g., time delay skew, rise time skew, amplitude skew, fiber glass skew, glass weave skew, fiber weave skew, phase skew, timing skew, line-to-line skew, positive/negative skew), or a difference between the respective durations of time in which signals travel along the cable 108, may occur. The difference in the time and speed of signal travel along the cable 108 may affect operation of the PCB 102, of the circuit 104, and/or of the module 106, such as different performance operations, including signal response behavior, signal integrity, link performance, bit-error-rate performance, communication channel budget, and/or electromagnetic interference. For example, signals can desynchronize and arrive at target destinations at undesirably different times to affect an integrity of communication between the circuit 104 and the module 106. Thus, it may be desirable to determine skew and performance impact caused by a certain amount of skew.

In some circumstances, a characteristic of the cable 108 may affect skew. For instance, a structure, a composition, a layout, and/or an arrangement of the cables, may provide a certain amount of skew and therefore achieve a particular performance upon implementation in the electronic system 100. As such, it may be desirable to determine a relationship between skew and performance related to cables to model a skew mask. Furthermore, in order to determine performance provided by a specific cable, the specific cable may be tested and compared with the skew mask. Although the present disclosure primarily discusses techniques with respect to implementation of cables for obtaining and providing signals to PCBs, including those used in Serdes applications, it should be noted that the techniques discussed herein may be used for implementation of cables for any other suitable application.

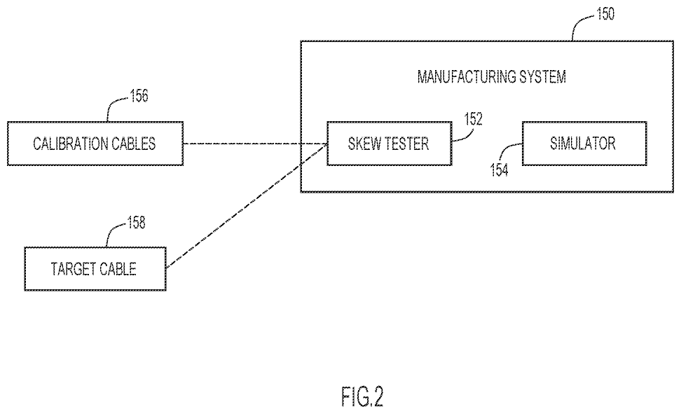

FIG. 2 is a schematic diagram of a manufacturing system 150 configured to perform a manufacturing operation, such as to manufacture an electronic system (e.g., the electronic system 100). The manufacturing system 150 includes a skew tester 152 configured to determine an amount of skew, as well as a corresponding signal loss value (e.g., a differential signal insertion loss value) due to skew, provided by different cables. The manufacturing system 150 also includes a simulator 154 (e.g., a run time domain serializer/deserializer (Serdes) simulator, a Serdes channel simulator, a channel operating margin (COM) tool) configured to determine or calculate a performance metric, such as a bit error rate (BER), a signal to noise ratio (SNR), and/or or a COM value for a simulated channel, based on various skew parameters. Thus, the skew tester 152 and the simulator 154 may cooperatively operate to determine a relationship between skew and performance.

For example, the manufacturing system 150 is configured to operate in a calibration phase to determine the relationship between skew and performance. During the calibration phase, the skew tester 152 is configured to determine the skew of various calibration cables 156, such as by transmitting test signals (e.g., a positive test signal, a negative test signal) through the calibration cables 156, then monitoring and comparing a time of propagation through the calibration cables 156.

In some circumstances, the skew of each calibration cable 156 is frequency dependent such that skew values and the signal loss values due to skew varies at different signal frequencies. As a result, each calibration cable 156 may have certain skew behavior property values (e.g., scattering parameters or S-parameters) provided by the varying skew. Such skew behavior property values may include a peak signal loss value due to skew, a signal frequency value at a peak skew value, and/or a periodicity value of skew.

The simulator 154 then uses the particular skew behavior property values of a calibration cable 156 to determine a performance metric. The performance metric indicates the performance achieved by the corresponding calibration cable 156 as a result of the varying skew at different signal frequencies. In this manner, the performance metric for a calibration cable 156 may be determined by first determining skew and signal loss via the skew tester 152 to identify the skew behavior property values and then determining the performance metric via the simulator 154 based on the skew behavior property values. By determining the respective performance metric for each different calibration cable 156, a relationship between skew and frequency to achieve a particular performance metric may be determined. In other words, skew thresholds for achieving a performance metric at different signal frequency values may be established by testing the calibration cables 156.

By way of example, a performance metric of 0.1 decibels (dB) COM value degradation or less due to skew is desirable for a particular implementation. During testing of the calibration cables 156 in which respective skew values and signal loss values of the calibration cables 156 may be determined, the simulator 154 may determine that the skew behavior property values of at least a portion of the calibration cables 156 achieve the COM value degradation of 0.1 dB. Consequently, the skew values of such calibration cables 156 (e.g., an average, such as mathematical mean/median, of the skew values) at different signal frequency values may be determined and established as the skew thresholds at the different signal frequency values to model a skew mask (e.g., an intra-pair skew mask), which may be a graphical/tabular representation of skew thresholds at various signal frequency values to achieve the COM value degradation of 0.1 dB.

The manufacturing system 150 may also determine whether a target cable 158 can be implemented to achieve a desirable performance metric based on a modeled skew mask. For example, the skew tester 152 may determine the skew of the target cable 158 at a particular signal frequency value. The determined skew may then be compared to the skew threshold at the particular signal frequency according to the skew mask related to the desirable performance metric. In response to determining the skew is below the skew threshold, thereby indicating the desirable performance metric may be achieved by the target cable 158 having the skew at the particular signal frequency value, the manufacturing system 150 may implement the target cable 158 (e.g., for transmitting signals with respect to a PCB). However, in response to determining the skew is at or above the skew threshold, thereby indicating the desirable performance metric may not be achieved by the target cable 158 having the skew at the particular signal frequency value, the manufacturing system 150 may discard the target cable 158 and avoid implementing the target cable 158. Thus, the manufacturing system 150 may utilize the skew mask to more readily determine whether the target cable 158 may be implemented, such as without having to determine signal loss values and/or use the simulator 154 to test the target cable 158 as well.

It should be noted that in some circumstances, cables may have different skew profiles. For example, the manner in which skew varies at different frequency values may be similar for a subset of cables but different for another subset of cables. Thus, to provide an accurate skew mask and cable performance evaluation based on a skew mask, the skew profile of each cable may be modeled, and the skew values of the cables having the same skew profile may be used to determine threshold skews to model a skew mask. Consequently, cables having different skew profiles, and therefore potentially significantly different skew behavior property values, are not used to inaccurately determine a threshold skew and/or a performance metric for a skew mask. Instead, cables having different skew profiles may be used to model different skew masks for the same performance metric.

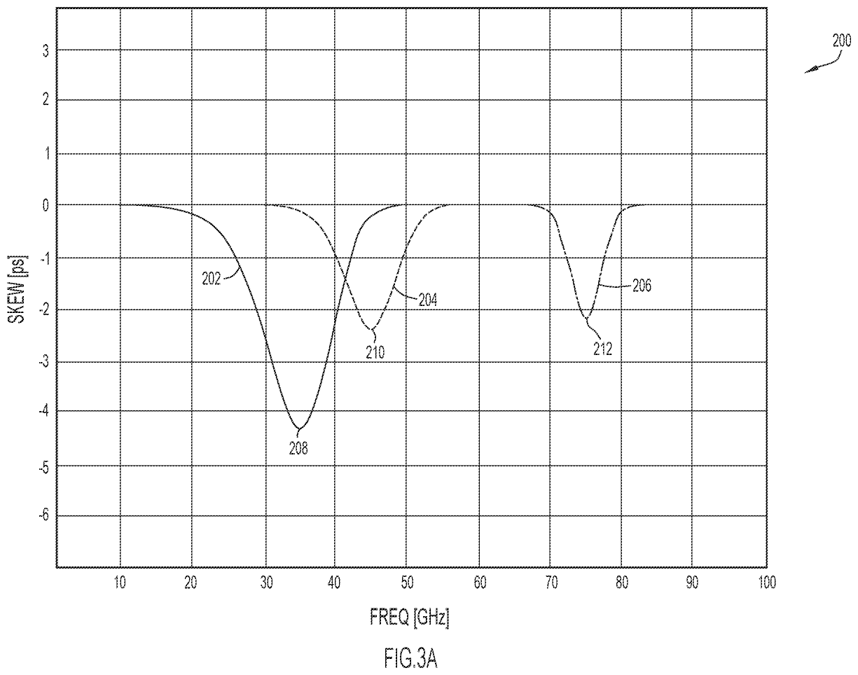

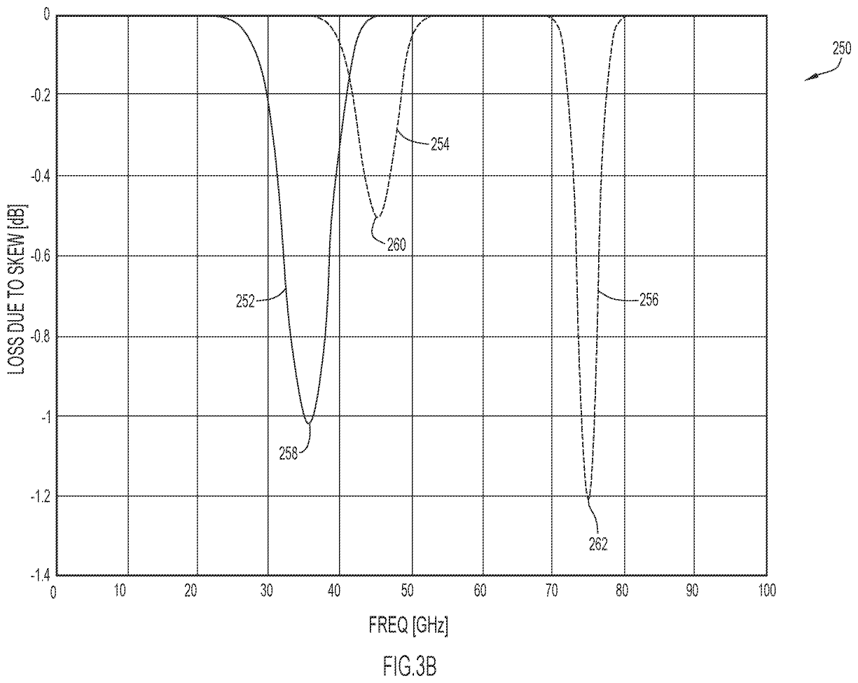

FIGS. 3A, 3B, 4A, 4B, 5A, and 5B illustrate respective graphical plots related to various skew profiles. Thus, the graphical plots indicate different possible skew values and signal loss values at varying signal frequency values, as well as associated differences in skew behavior property values, across the different skew profiles. Although three different skew profiles are discussed herein, it should be noted that in additional or alternative embodiments, there may be other skew profiles and/or subsets of the depicted skew profiles identifiable for modeling respective skew masks.

FIG. 3A is a graphical plot 200 illustrating skew (in picoseconds (ps)) at varying signal frequency values (in gigahertz (GHz)) for a first profile, which may be a Gaussian skew profile or single peak profile. The graphical plot 200 includes a first plot 202 corresponding to a first cable, a second plot 204 corresponding to a second cable, and a third plot 206 corresponding to a third cable. Each of the plots 202, 204, 206 includes a single peak in which skew is at its highest absolute value, whereas the skews outside of the respective peaks are substantially the same (e.g., at 0 ps). As such, the first plot 202 includes a first peak 208, the second plot 204 includes a second peak 210, and the third plot 206 includes a third peak 212. The peaks 208, 210, 212 are different from one another. For example, the first peak 208 has a first skew value (e.g., a relatively greater absolute skew value) and occurs at a first signal frequency value (e.g., a relatively smaller signal frequency value), the second peak 210 has a second skew value (e.g., an intermediate absolute skew value), different from the first skew value, and occurs at a second signal frequency value (e.g., an intermediate signal frequency value), different from the first signal frequency value, and the third peak 212 has a third skew value (e.g., a relatively smaller absolute skew value), different from the first skew value and the second skew value, and occurs at a third signal frequency value (e.g., a relatively greater signal frequency value), different from the first signal frequency value and the second signal frequency value. As such, even though each of the plots 202, 204, 206 includes a common characteristic of having a single peak, the plots 202, 204, 206 have different peak sizes, as well as different peak locations.

FIG. 3B is a graphical plot 250 illustrating signal loss due to skew (in decibels (dB)) at varying signal frequency values for the first profile. The graphical plot 250 includes a first plot 252 indicating signal loss due to skew for the first cable, a second plot 254 indicating signal loss due to skew for the second cable, and a third plot 256 indicates signal loss due to skew for the third cable. Thus, the first plot 254 may indicate signal loss caused by skew depicted by the first plot 202 of the graphical plot 200, the second plot 254 may indicate signal loss caused by skew depicted by the second plot 204 of the graphical plot 200, and the third plot 256 may indicate signal loss caused by skew depicted by the third plot 206 of the graphical plot 200. Each of the plots 252, 254, 256 includes a single peak, but different peak sizes and peak locations. For instance, the first plot 252 may include a first peak 258 that has a first signal loss value (e.g., an intermediate absolute signal loss value) occurring at a first signal frequency value (e.g., the relatively smaller signal frequency value at which the first peak 208 occurs), the second plot 254 may include a second peak 260 (e.g., a relatively smaller absolute signal loss value) occurring at a second signal frequency value (e.g., the intermediate signal frequency value at which the second peak 210 occurs), and the third plot 256 may include a third peak 262 that has a third signal loss value (e.g., a relatively greater absolute signal loss value) occurring at a third signal frequency value (e.g., the relatively greater signal frequency value at which the third peak 212 occurs).

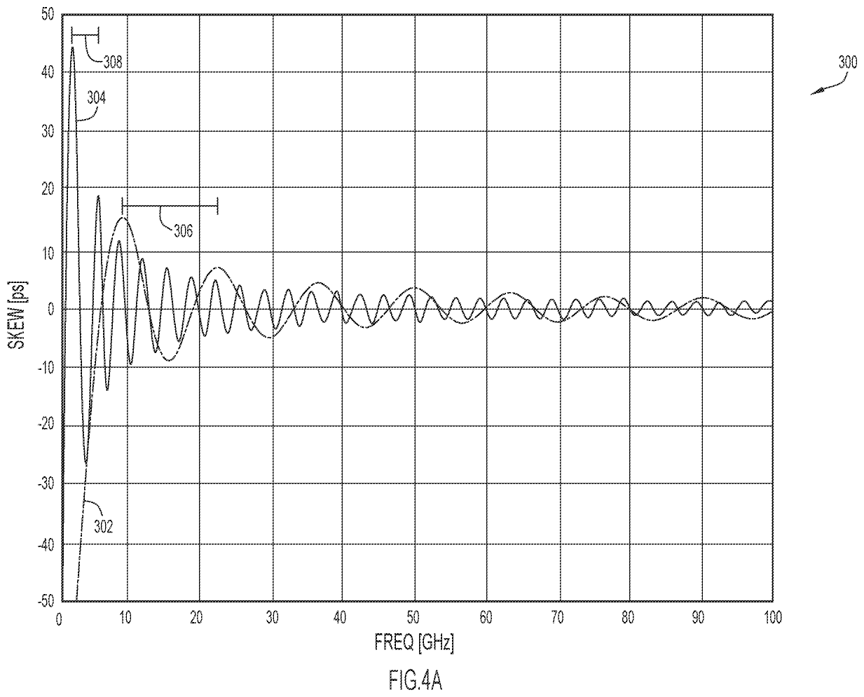

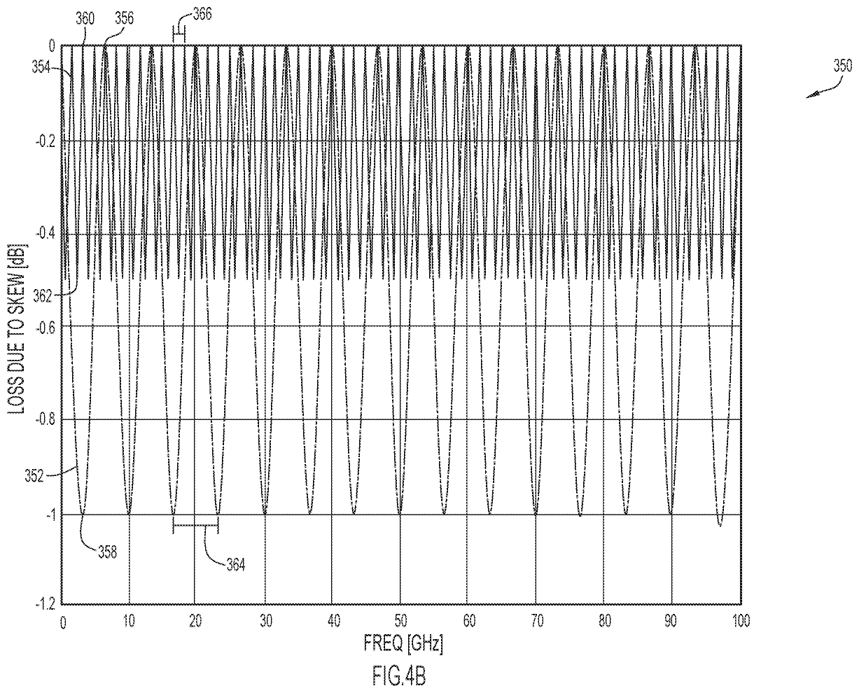

FIG. 4A is a graphical plot 300 illustrating skew (in ps) at varying signal frequency values (in GHz) for a second profile, which may be a damped oscillated skew profile. The graphical plot 300 includes a first plot 302 corresponding to a first cable and a second plot 304 corresponding to a second cable. Each of the first plot 302 and the second plot 304 includes skew values that alternate between positive values (e.g., positive peaks) and negative values (e.g., negative peaks) across varying signal frequencies, and the absolute value of the skew values is smaller at greater signal frequencies. However, the skew values of the first plot 302 may be different than those of the second plot 304 at certain signal frequencies. By way of example, the absolute skew values of the second plot 304 may be greater than those of the first plot 302 at smaller signal frequencies. Additionally or alternatively, a first periodicity 306 between adjacent positive peaks or adjacent negative peaks (e.g., a difference in signal frequency value occurrences of adjacent positive peaks or of adjacent negative peaks) of the first plot 302 may be different (e.g., greater) than a second periodicity 308 between adjacent positive peaks or adjacent negative peaks of the second plot 304. Therefore, even though each of the plots 302, 304 includes a common characteristic of having skews that oscillate between positive and negative values, the plots 302, 304 have different skew values and periodicities 306, 308.

FIG. 4B is a graphical plot 350 illustrating signal loss due to skew (in dB) at varying signal frequency values for the second profile. The graphical plot 350 includes a first plot 352 indicating signal loss due to skew for the first cable and a second plot 354 indicating signal loss due to skew for the second cable. The signal loss values for each of the plots 352, 354 oscillate between a respective high value and a respective low value. Thus, the signal loss values for the first plot 352 oscillate between a first high value 356 (e.g., 0 dB) and a first low value 358 (e.g., −1 dB), whereas the signal loss values for the second plot 354 oscillate between a second high value 360 (e.g., 0 dB), substantially equal to the first high value 356, and a second low value 362 (e.g., −0.5 dB), substantially different from the first low value 358. Moreover, a first periodicity 364 between adjacent high values 356 or adjacent low values 358 of the first plot 352 is different from (e.g., greater than) a second periodicity 366 between adjacent high values 360 or adjacent low values 362 of the second plot 354. In this manner, the signal loss values for the first plot 352 and for the second plot 354 oscillate between different high values 356, 360 and low values 358, 362 and at different periodicities 364, 366.

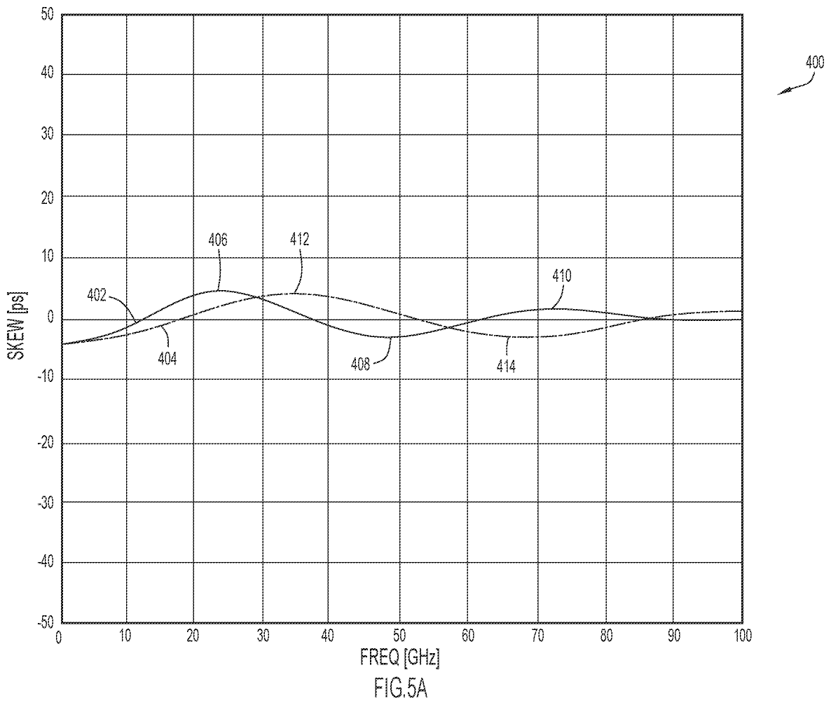

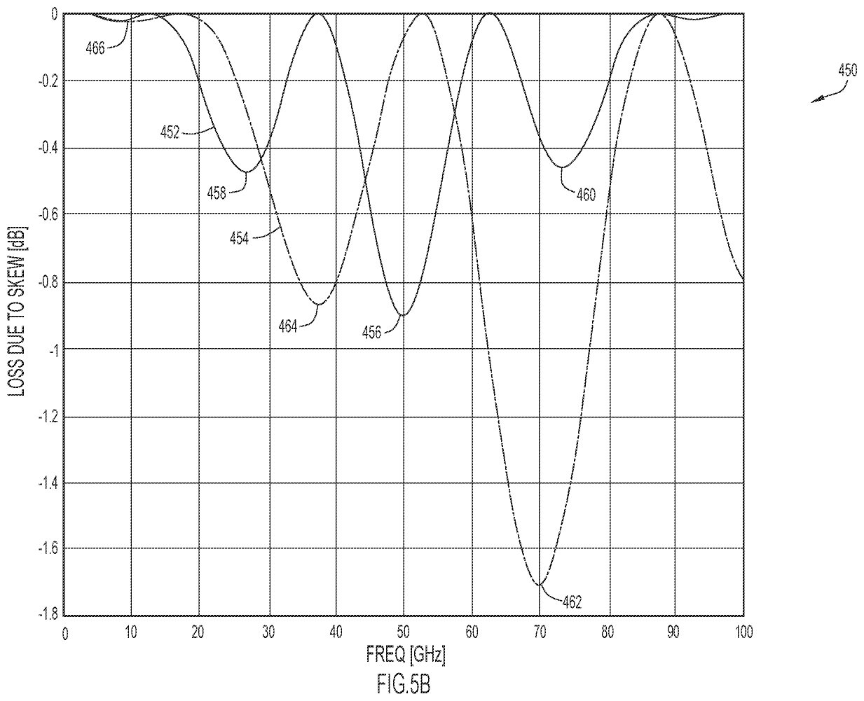

FIG. 5A is a graphical plot 400 illustrating skew (in ps) at varying signal frequency values (in GHz) for a third profile, which may be a multiple peak profile. The graphical plot 400 includes a first plot 402 corresponding to a first cable and a second plot 404 corresponding to a second cable. The first plot 402 includes a first positive peak 406, a first negative peak 408, and a second positive peak 410, and the second plot 404 includes a third positive peak 412 and a second negative peak 414. Thus, the plots 402, 404 include a different quantity of peaks (e.g., a different quantity of positive peaks). Moreover, the peaks occur at different signal frequencies in that the third positive peak 412 of the second plot 404 occurs at a different signal frequency than that in which the first positive peak 406 and the second positive peak 410 of the first plot 402 occurs, and the second negative peak 414 of the second plot 404 occurs at a different signal frequency than that in which the first negative peak 408 of the second plot 404 occurs.

FIG. 5B is a graphical plot 450 illustrating signal loss due to skew (in dB) at varying signal frequency values for the third profile. The graphical plot 450 includes a first plot 452 indicating signal loss due to skew for the first cable and a second plot 454 indicating signal loss due to skew for the second cable. The first plot 452 includes a first peak 456 (e.g., a first major peak) having a relatively greater absolute signal loss value, a second peak 458 (e.g., a first minor peak) having an intermediate absolute signal loss value, and a third peak 460 (e.g., a second minor peak) having another intermediate absolute signal loss value. The second plot 454 includes a fourth peak 462 (e.g., a second major peak) having another relatively greater absolute signal loss value, a fifth peak 464 (e.g., a third minor peak) having yet another intermediate absolute signal loss value, and a sixth peak 466 (e.g., a fourth minor peak) having a relatively lesser absolute signal loss value. The respective peaks 456, 458, 460, 462, 464, 466 of the plots 452, 454 may have substantially different signal loss values. For example, the fourth peak 462 of the second plot 454 may have an absolute signal loss value that is much greater than that of the first peak 456 of the first plot 452 and that occurs at a greater signal frequency than that in which the first peak 456 of the first plot 452 occurs. Moreover, the sixth peak 466 of the second plot 454 may have an absolute signal loss value that is much smaller than that of the second peak 458 and/or of the third peak 460 of the first plot 452 and that occurs at a much smaller signal frequency than that in which the second peak 458 and/or the third peak 460 of the first plot 452 occurs.

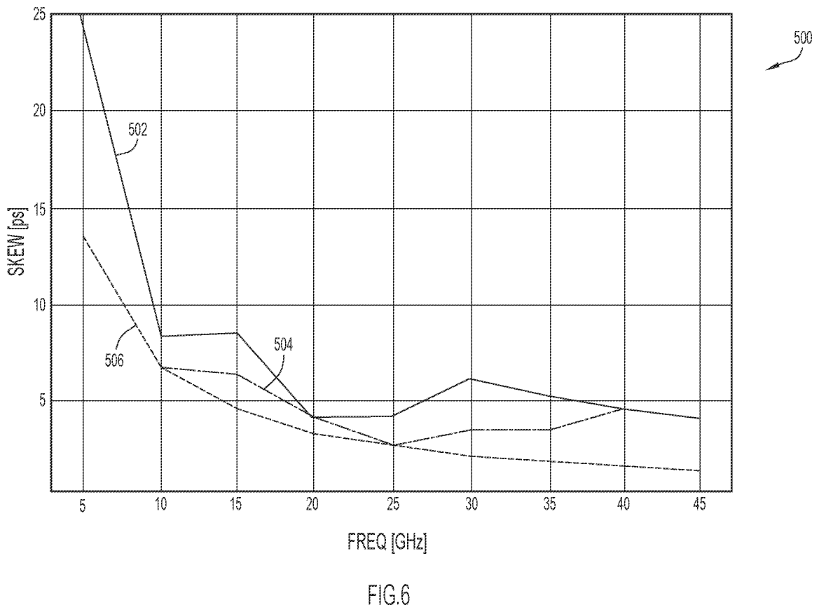

FIG. 6 provides a graphical plot 500 of a first skew mask 502, a second skew mask 504, and a third skew mask 506 for different skew profiles. For example, the first skew mask 502 may correspond to the first skew profile described in FIGS. 3A and 3B, the second skew mask 504 may correspond to the second skew profile described in FIGS. 4A and 4B, and the third skew mask 506 may correspond to the third skew profile described in FIGS. 5A and 5B. Each skew mask 502, 504, 506 is determined using the techniques discussed herein, including determining the skews of different cables (e.g., the calibration cables 156) at various signal frequencies (e.g., via the skew tester 152), identifying the skew behavior property values based on the skews, and determining the performance metric based on the skew behavior property values (e.g., via the simulator 154). In some embodiments, the skew masks 502, 504, 506 may be stored and retrievable for reference, such as for comparison with measurements of another cable to evaluate performance of the cable.

Because the different skew profiles have different skew characteristics, such as different peak signal losses, different signal frequency values at peak skews, and/or different periodicities, the skew masks 502, 504, 506 respectively corresponding to the skew profiles may be substantially different from one another. Indeed, each skew mask 502, 504, 506 may accurately represent its corresponding skew profile and not another skew profile.

Each of the skew masks 502, 504, 506 provides a curve indicating threshold skews (in ps) at different signal frequencies (in GHz) to achieve a particular target performance metric for the corresponding skew profile. In other words, at a particular signal frequency, each of the skew masks 502, 504, 506 indicates the threshold skew to achieve its related target performance metric. For instance, each of the skew masks 502, 504, 506 may indicate skew thresholds to achieve a target performance metric of 0.1 dB COM value degradation. At a signal frequency of 10 GHZ, the first skew mask 502 provides a threshold skew value of about 8 ps to achieve 0.1 dB COM value degradation, whereas each of the skew masks 504 and the skew masks 506 provides a threshold skew value of about 7 ps to achieve 0.1 dB COM value degradation. Consequently, for a cable having the first skew profile, a skew above 8 ps (e.g., 9 ps) at 10 GHz of signal frequency would not achieve 0.1 dB COM value degradation, but a skew below 8 ps (e.g., 7 ps) at 10 GHz of signal frequency would achieve 0.1 dB COM value degradation. Moreover, for a cable having the second skew profile or the third skew profile, a skew above 7 ps (e.g., 8 ps) at 10 GHz of signal frequency would not achieve 0.1 dB COM value degradation, but a skew below 7 ps (e.g., 6 ps) at 10 GHz of signal frequency would achieve 0.1 dB COM value degradation. Thus, the skew masks 502, 504, 506 may be used to determine whether a cable can achieve the associated target performance metric based on the skew of the cable.

Because skew may be frequency dependent and may therefore change at various signal frequencies, the threshold skew to achieve a particular performance metric may also change at different signal frequencies. Thus, the skew masks may provide a more accurate representation of the different threshold skews for achieving a particular performance metric at varying signal frequencies, such as in comparison with data that assumes a constant amount of skew at different signal frequencies (e.g., skew that is not frequency dependent).

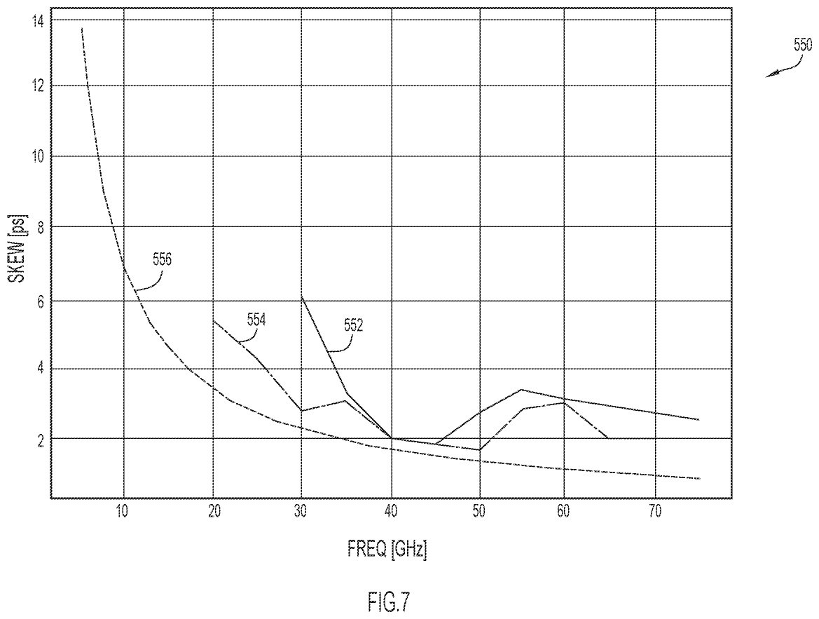

It should be noted that different skew masks may be modeled for different applications, such as to achieve a different target performance metric and/or for a different data rate transmission of signal. FIG. 7 provides a graphical plot 550 of a first skew mask 552, a second skew mask 554, and a third skew mask 556 for different skew profiles. For instance, the first skew mask 552 may correspond to the first skew profile described in FIGS. 3A and 3B, the second skew mask 554 may correspond to the second skew profile described in FIGS. 4A and 4B, and the third skew mask 556 may correspond to the third skew profile described in FIGS. 5A and 5B. The skew masks 552, 554, 556 may indicate the threshold skews at different signal frequencies to achieve the same particular target performance metric (e.g., 0.1 dB COM value degradation) as that corresponding to the skew masks 502, 504, 506. However, the skew masks 552, 554, 556 may be applicable for a different data rate transmission than that related to the skew masks 502, 504, 506. By way of example, the skew masks 502, 504, 506 of the graphical plot 500 may be applicable for 112 Gbps (e.g., 112 Gbps pulse amplitude modulation with four levels (PAM4)), whereas the skew masks 552, 554, 556 of the graphical plot 550 may be applicable for 112 Gbps (e.g., 224 Gbps PAM4). Thus, a different manner of testing cables (e.g., by transmitting signals at different data rates) may be used to model the skew masks 552, 554, 556 in comparison to modeling the skew masks 502, 504, 506.

Indeed, cables may have different skew-related parameters for different data transmission rates. Therefore, the related skew masks may also be different for different data transmission rates. For this reason, modeling skew masks specifically applicable to a particular data transmission rate may better indicate performance at that particular data transmission rate. Thus, performance of a cable may be better evaluated by selecting the corresponding skew mask associated with similar applications (e.g., the data transmission rate). That is, for example, for a cable to be implemented in a 224 Gbps data rate transmission application, one of the skew masks 552, 554, 556 applicable to 224 Gbps data rate transmission, instead of one of the skew masks 502, 504, 506 applicable to 112 Gbps data rate transmission, may be selected for comparison to determine whether a target performance metric is achieved with the cable based on its skew at 224 Gbps data rate transmission.

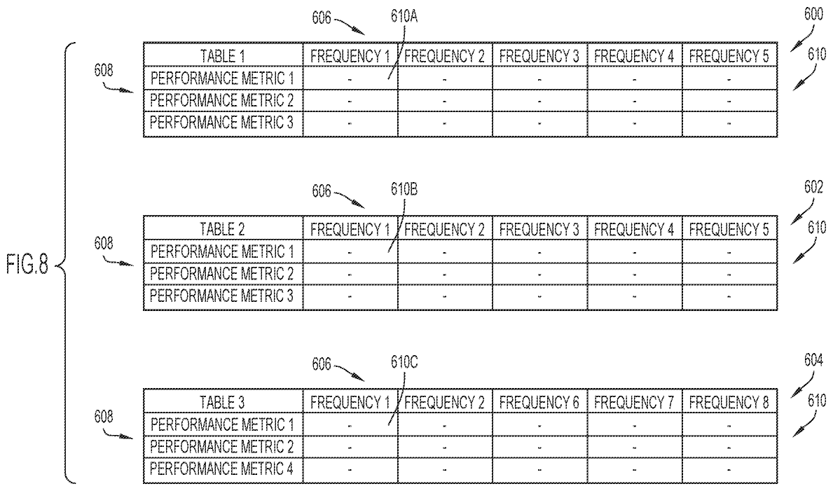

Skew masks can also be modeled in a different format. FIG. 8 provides skew masks stored in a tabular format. In particular, a first table 600 (e.g., a first database table) may provide skew masks for the first skew profile, a second table 602 (e.g., a second database table) may provide skew masks for the second profile, and a third table 604 (e.g., a third database table) may provide skew masks for a third profile. Each table 600, 602, 604 includes frequency fields 606 of various signal frequency values, performance metric fields 608 of various performance metric values, and threshold skew records 610 of various threshold skew values for corresponding signal frequency values and performance metric values. Similar to the skew masks in graphical plot format, the skew masks in tabular format provide the threshold skew values to achieve a target performance metric at various signal frequencies. By way of example, the first table 600 may include a first skew record 610A indicating a first threshold skew value to achieve a first performance metric value at a first signal frequency value, the second table 602 may include a second skew record 610B indicating a second threshold skew value, different from the first threshold skew value of the first skew record 610A, to achieve the first performance metric value at the first signal frequency value, and the third table 604 may include a third skew record 610C indicating a third threshold skew value, different from the first skew record 610A and from the second skew record 610B, to achieve the first performance metric value at the first signal frequency value.

The tables 600, 602, 604 may have different signal frequency values at the respective signal frequency fields 606 and/or different performance metric values at the respective performance metric fields 608. As an example, the first table 600 and the second table 602 may include the same frequency fields 606 (e.g., the same signal frequency values) and the same performance metric fields 608 (e.g., the same performance metric values). However, the third table 604 may include different frequency fields 606 (e.g., different signal frequency values) and/or different performance metric fields 608 (e.g., different performance metric values). Indeed, each table 600, 602, 604 may provide threshold skew values for any combination of frequency fields 606 and performance metric fields 608.

The tables 600, 602, 604 may then be retrieved and referenced for comparison to a provided threshold skew value. By way of example, a cable may be tested to determine its skew profile, and one of the tables 600, 602, 604 is selected based on its association with the skew profile. The target performance metric value and signal frequency value associated with the application of the cable may then be determined, and the skew record 610 corresponding to the target performance metric value and signal frequency value at the selected table may be identified for comparison with the skew of the cable at the signal frequency value. The skew of the cable being at or above the threshold skew value of the skew record 610 may indicate the cable does not achieve the target performance metric, and the skew of the cable being below the threshold skew value of the skew record 610 may indicate the cable achieves the target performance metric.

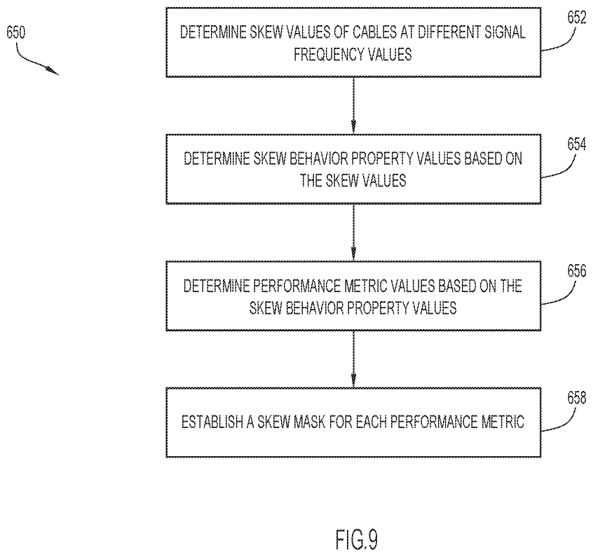

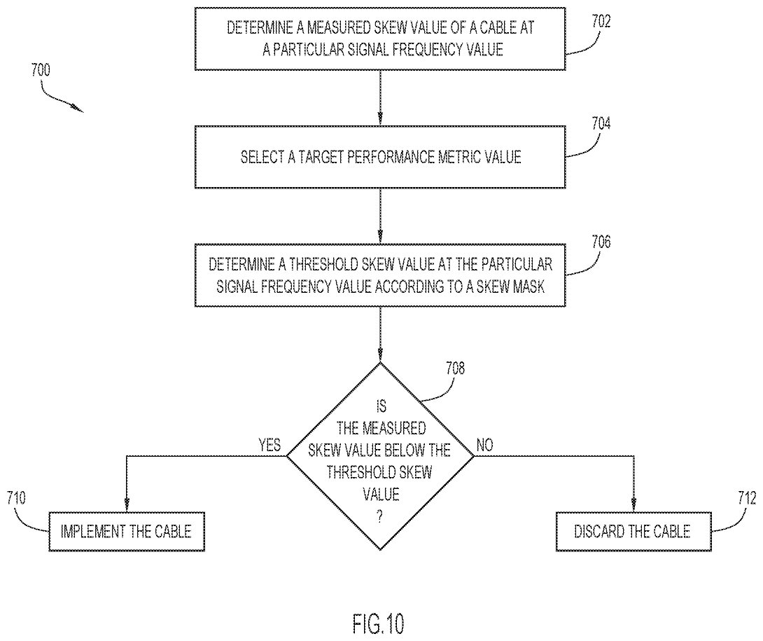

Each of FIGS. 9 and 10 illustrates a respective method related to operations based on skew. In some embodiments, the methods may be performed by the same entity, such as the manufacturing system 150. In additional or alternative embodiments, operations of the methods may be performed by different entities. It should be noted that the operations of the method may be performed differently than depicted. For example, an additional operation may be performed, and/or any of the operations may be performed differently, in a different order, or not performed. Furthermore, the respective operations of the methods may be performed in any manner relative to one another, such as sequentially (e.g., in response to one another) and/or concurrently (e.g., in parallel with one another).

FIG. 9 is a flowchart of a method 650 for modeling skew masks that include threshold skews for achieving target performance metrics at various signal frequencies. At step 652, skew values of cables (e.g., calibration cables) at different signal frequency values may be determined. By way of example, signals may be transmitted through the cables, and respective times of signal propagation through the cables may be determined and compared with one another. Signal loss values due to skew may also be determined for the cables at the different signal frequency values. The cables may exhibit frequency dependent skew behavior in that skew varies at different signal frequencies.

At step 654, skew behavior property values may be determined based on the skew values and/or the signal loss values. The skew behavior property values may include S-parameters, such as a peak signal loss value due to skew, a signal frequency value at a peak skew value, and/or a periodicity value of skew. At step 656, a performance metric value, such as a BER, an SNR, and/or a COM value, may be determined based on the skew behavior property values. For example, based on the skew behavior property values for one of the cables, a particular performance metric value may be determined for the cable. Consequently, various performance metric values may be determined based on the different cables and their associated skew values at various signal frequency values.

At step 658, a skew mask may be modeled for each performance metric based on the performance metric values determined for the skew behavior property values. Each skew mask provides threshold skew values that enable the performance metric to be achieved at various signal frequency values. In other words, each skew mask includes a relationship between the skew values and the signal frequency values to achieve each performance metric. Thus, the skew values determined for the cables at different signal frequency values and ultimately used to determine performance metric values may be used to establish the threshold skew values to achieve such performance metric values. The skew masks may be stored in a graphical format, in a tabular format, and/or in any other suitable format (e.g., an equation) that can be retrieved for subsequent reference.

In some embodiments, different skew masks may be modeled for different skew profiles. For example, after the skew values of cables are determined at different signal frequency values, the cables may be categorized into different skew profiles based on their respective skew values. The skew behavior property values and performance metric values may then be separately determined for the cables in the different skew profiles to model separate skew masks for each skew profile. Additionally or alternatively, different skew masks may be determined for different data rate transmissions. To this end, skew values may be determined in various manners, such as by transmitting signals at different data transmission rates through the cables, to ultimately model a relevant skew mask. Indeed, skew masks that correspond more closely to a particular application may be modeled to provide a more accurate representation of the threshold skews for achieving a target performance metric at various signal frequencies.

FIG. 10 is a flowchart of a method 700 related to usage of a cable based on its skew. At step 702, a measured skew value of the cable may be determined at a particular signal frequency value. For instance, signals may be transmitted through the cable, and respective times of signal propagation through the cable may be determined and compared with one another.

At step 704, a target performance metric may be selected. The target performance metric may indicate a desirable performance metric to be achieved in a potential application of the cable (e.g., coupling electronic components to one another). At step 706, a threshold skew value at the particular signal frequency values may be determined according to a skew mask. The skew mask may have been previously modeled via the method 650 and stored. Thus, the skew mask may be retrieved for comparison with the cable. In some embodiments, multiple skew masks related to different target performance metrics may be stored, and the skew mask related to the selected target performance metric value of the cable may be referenced. The skew mask provides a relationship between threshold skew values and signal frequency values to achieve the target performance metric. That is, the skew mask associates threshold skew values with respective, corresponding signal frequency values to achieve the target performance metric related to the skew mask. In particular, the threshold skew value may be selected from the skew mask based on the skew mask associating the threshold skew value with the particular signal frequency value.

At step 708, a determination may be made regarding whether the measured skew value of the cable is below the determined threshold skew value. At step 710, in response to a determination that the measured skew value is below the determined threshold skew value, the cable may be implemented. For instance, the measured skew value being below the determined threshold skew value may indicate that the target performance metric value may be achieved upon implementation of the cable. However, at step 712, in response to a determination that the measured skew value is at or above the determined threshold value, the cable may be discarded or otherwise not implemented. For example, the measured skew value being at or above the determine threshold skew value may indicate that the target performance metric value may not be achieved upon implementation of the cable. For this reason, the cable may not be implemented to avoid undesirable performance caused by the cable.

In some embodiments, implementation of the cable may include usage of the cable to propagate signals (e.g., differential signals), such as for a PCB. Thus, the method 700 may be performed to determine the PCB and/or an electronic component coupled to the PCB operates desirably via the cable. For example, implementing a cable having a skew below the threshold skew at an applicable signal frequency may ensure that an electronic component (e.g., of the PCB, communicatively coupled to the PCB) receives signals propagated along the cable at a desirable timing. Thus, after determining the skew of the cable is below the threshold skew, the cable may be implemented and signals may be transmitted along the cable (e.g., to operate a PCB based on the signals).

Certain operations of the method 700 may be repeatedly performed. For example, in response to a determination that the measured skew value of the cable is below the determined threshold skew value, a skew of an additional cable at the particular signal frequency value may be tested and compared with the threshold skew value at the particular signal frequency value to determine whether the additional cable may be implemented. In this way, cables may be continually tested until a determination is made that one of the cables may be implemented based on its measured skew value.

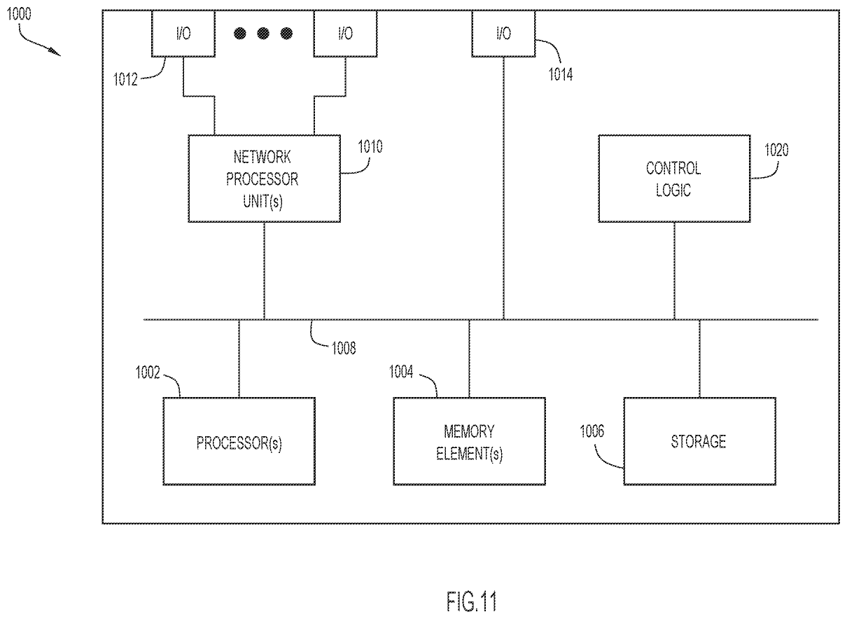

FIG. 11 is a hardware block diagram of a networking device that may perform functions associated with any combination of operations in connection with the techniques discussed herein, such as that with respect to the manufacturing system 150. It should be appreciated that FIG. 11 provides an illustration of one example embodiment and does not imply any limitations with regard to the environments in which different example embodiments may be implemented. Many modifications to the depicted environment may be made.

In at least one embodiment, the device 1000 may include one or more processor(s) 1002, one or more memory element(s) 1004, storage 1006, a bus 1008, one or more network processor units 1010, one or more input/output (I/O) interface(s) 1012, 1014, and control logic 1020. In various embodiments, instructions associated with logic for device 1000 can overlap in any manner and are not limited to the specific allocation of instructions and/or operations described herein.

In at least one embodiment, processor(s) 1002 is/are at least one hardware processor configured to execute various tasks, operations and/or functions for device 1000 as described herein according to software and/or instructions configured for device 1000. Processor(s) 1002 (e.g., a hardware processor) can execute any type of instructions associated with data to achieve the operations detailed herein. In one example, processor(s) 1002 can transform an element or an article (e.g., data, information) from one state or thing to another state or thing. Any of potential processing elements, microprocessors, digital signal processor, baseband signal processor, modem, PHY, controllers, systems, managers, logic, and/or machines described herein can be construed as being encompassed within the broad term ‘processor’.

In at least one embodiment, one or more memory element(s) 1004 and/or storage 1006 is/are configured to store data, information, software, and/or instructions associated with device 1000, and/or logic configured for memory element(s) 1004 and/or storage 1006. For example, any logic described herein (e.g., control logic 1020) can, in various embodiments, be stored for device 1000 using any combination of memory element(s) 1004 and/or storage 1006. Note that in some embodiments, storage 1006 can be consolidated with one or more memory elements 1004 (or vice versa), or can overlap/exist in any other suitable manner. In one or more example embodiments, process data is also stored in the one or more memory elements 1004 for later evaluation and/or process optimization.

The bus 1008 can be implemented with any architecture designed for passing control, data and/or information between processors, memory elements/storage, peripheral devices, and/or any other hardware and/or software components that may be configured for device 1000. In at least one embodiment, bus 1008 may be implemented as a fast kernel-hosted interconnect, potentially using shared memory between processes (e.g., logic), which can enable efficient communication paths between the processes.

I/O interface(s) 1012, 1014 allow for input and output of data and/or information with other entities that may be connected to device 1000. For example, I/O interface(s) 1012, 1014 may provide a connection to external devices such as a keyboard, keypad, a touch screen, and/or any other suitable input device now known or hereafter developed. In some instances, external devices can also include portable computer readable (non-transitory) storage media such as database systems, thumb drives, portable optical or magnetic disks, and memory cards. The I/O interface(s) 1012 may communicatively couple to the bus 1008 via the network processor unit(s) 1010, whereas the I/O interface(s) 1014 may be directly communicatively coupled to the bus 1008 (e.g., without usage of the network processor unit(s) 1010). Thus, the I/O interface(s) enable one or more elements of the device 1000 to communicate in order to exchange information and/or data.

In various embodiments, control logic 1020 can include instructions that, when executed, cause processor(s) 1002 to perform operations, which can include, but not be limited to, providing overall control operations of computing device; interacting with other entities, systems, etc. described herein; maintaining and/or interacting with stored data, information, parameters, etc. (e.g., memory element(s), storage, data structures, databases, tables, etc.); combinations thereof; and/or the like to facilitate various operations for embodiments described herein.

The programs described herein (e.g., control logic 1020) may be identified based upon the application(s) for which they are implemented in a specific embodiment. However, it should be appreciated that any particular program nomenclature herein is used merely for convenience, and thus the embodiments herein should not be limited to use(s) solely described in any specific application(s) identified and/or implied by such nomenclature.

In some aspects, the techniques described herein relate to a method including: determining a plurality of skew values of a plurality of cables, wherein each skew value of the plurality of skew values indicates a time of signal propagation along a respective cable of the plurality of cables at a respective signal frequency value of a plurality of signal frequency values, and the plurality of skew values are frequency dependent and vary at the plurality of signal frequency values; determining a plurality of skew behavior property values for each cable of the plurality of cables based on the plurality of skew values; determining a performance metric value for each skew behavior property value of the plurality of skew behavior property values to generate a plurality of performance metric values; determining a relationship between the plurality of skew values and the plurality of signal frequency values at each performance metric value of the plurality of performance metric values based on the performance metric value for each skew behavior property value; and coupling a first electronic component and a second electronic component to one another using a new cable, separate from the plurality of cables, based on the relationship between the plurality of skew values and the plurality of signal frequency values at each performance metric value.

In some aspects, the techniques described herein relate to a method, wherein coupling the first electronic component and the second electronic component to one another using the new cable based on the relationship between the plurality of skew values and the plurality of signal frequency values includes at each performance metric value includes: determining a new skew value for the new cable at a selected signal frequency value of the plurality of signal frequency values; determining a target performance metric value of the plurality of performance metric values; comparing the new skew value to a selected skew value of the plurality of skew values based on the selected skew value corresponding to the selected signal frequency value according to the relationship between the plurality of skew values and the plurality of signal frequency values at the target performance metric value; and coupling the first electronic component and the second electronic component to one another using the new cable based on the new skew value being below the selected skew value.

In some aspects, the techniques described herein relate to a method, further including propagating signals through the new cable between the first electronic component and the second electronic component.

In some aspects, the techniques described herein relate to a method, wherein at least one of the first electronic component or the second electronic component includes a printed circuit board.

In some aspects, the techniques described herein relate to a method, further including determining a selected skew profile from a plurality of skew profiles for each cable of the plurality of cables based on its plurality of skew values, wherein determining the relationship between the plurality of skew values and the plurality of signal frequency values at each performance metric value includes determining a respective relationship between the plurality of skew values and the plurality of signal frequency values for each skew profile of the plurality of skew profiles at each performance metric value.

In some aspects, the techniques described herein relate to a method, wherein coupling the first electronic component and the second electronic component to one another using the new cable includes: determining a new plurality of skew values of the new cable; determining a skew profile of the plurality of skew profiles of the new cable based on the new plurality of skew values; determining a new skew value of the new plurality of skew values of the new cable at a selected signal frequency value of the plurality of signal frequency values; determining a target performance metric value of the plurality of performance metric values; comparing the new skew value to a selected skew value of the plurality of skew values based on the selected skew value corresponding to the selected signal frequency value according to the respective relationship between the plurality of skew values and the plurality of signal frequency values for the skew profile of the new cable at the target performance metric value; and coupling the first electronic component and the second electronic component to one another using the new cable based on the new skew value being below the selected skew value.

In some aspects, the techniques described herein relate to a method, wherein determining the relationship between the plurality of skew values and the plurality of signal frequency values at each performance metric value includes determining a respective relationship between the plurality of skew values and the plurality of signal frequency values for each data rate transmission of a plurality of data rate transmissions at each performance metric value.

In some aspects, the techniques described herein relate to a method, wherein coupling the first electronic component and the second electronic component to one another using the new cable includes: determining a new plurality of skew values of the new cable; determining a selected data rate transmission of the plurality of data rate transmissions; determining a new skew value of the new plurality of skew values of the new cable at a selected signal frequency value of the plurality of signal frequency values; determining a target performance metric value of the plurality of performance metric values; comparing the new skew value to a selected skew value of the plurality of skew values based on the selected skew value corresponding to the selected signal frequency value according to the respective relationship between the plurality of skew values and the plurality of signal frequency values for the selected data rate transmission at the target performance metric value; and coupling the first electronic component and the second electronic component to one another using the new cable based on the new skew value being below the selected skew value.

In some aspects, the techniques described herein relate to a method, further including: storing the relationship between the plurality of skew values and the plurality of signal frequency values at each performance metric value; and retrieving the relationship between the plurality of skew values and the plurality of signal frequency values at each performance metric value from storage to couple the first electronic component and the second electronic component to one another using the new cable based on the relationship between the plurality of skew values and the plurality of signal frequency values at each performance metric value.

In some aspects, the techniques described herein relate to a method, wherein the relationship between the plurality of skew values and the plurality of signal frequency values at each performance metric value is stored as one or more database tables.

In some aspects, the techniques described herein relate to a method including: determining a measured skew value of a cable at a particular signal frequency value, wherein the measured skew value indicates a time of signal propagation along the cable and is frequency dependent; selecting a target performance metric value; selecting a skew mask from a plurality of skew masks based on the skew mask corresponding to the target performance metric value, wherein the skew mask associates a plurality of threshold skew values with respective, corresponding signal frequency values to achieve the target performance metric value; identifying a threshold skew value of the plurality of threshold skew values based on the threshold skew value being associated with the particular signal frequency value according to the skew mask; and coupling a first electronic component and a second electronic component to one another using the cable in response to determining the measured skew value is below the threshold skew value.

In some aspects, the techniques described herein relate to a method, including: determining an additional measured skew value of an additional cable at the particular signal frequency value; and discarding the additional cable in response to determining the additional measured skew value is at or above the threshold skew value.

In some aspects, the techniques described herein relate to a method, wherein each skew mask of the plurality of skew masks corresponds to a respective skew profile of a plurality of skew profiles, and wherein selecting the skew mask from the plurality of skew masks includes: determining a plurality of measured skew values of the cable at various signal frequency values, the plurality of measured skew values including the measured skew value, and the various signal frequency values including the particular signal frequency value; selecting a selected skew profile from the plurality of skew profiles for the cable based on the plurality of measured skew values of the cable at the various signal frequency values; and selecting the skew mask from the plurality of skew masks based on the skew mask corresponding to the target performance metric value and the selected skew profile.

In some aspects, the techniques described herein relate to a method, wherein each skew mask of the plurality of skew masks corresponds to a respective data rate transmission of a plurality of data rate transmissions, and wherein selecting the skew mask from the plurality of skew masks includes: determining a selected data rate transmission of the plurality of data rate transmissions for the cable; and selecting the skew mask from the plurality of skew masks based on the skew mask corresponding to the target performance metric value and the selected data rate transmission.

In some aspects, the techniques described herein relate to a method, further including: determining an additional measured skew value of an additional cable at the particular signal frequency value; selecting an additional target performance metric value; selecting an additional skew mask from the plurality of skew masks based on the additional skew mask corresponding to the additional target performance metric value, wherein the additional skew mask associates an additional plurality of threshold skew values with additional, respective, corresponding signal frequency values to achieve the additional target performance metric value; identifying an additional threshold skew value of the additional plurality of threshold skew values based on the additional threshold skew value being associated with the particular signal frequency value according to the additional skew mask; and coupling a third electronic component and a fourth electronic component to one another using the additional cable in response to determining the additional measured skew value is below the additional threshold skew value.

In some aspects, the techniques described herein relate to a method, further including: determining an additional measured skew value of an additional cable at an additional particular signal frequency value; identifying an additional threshold skew value of the plurality of threshold skew values based on the additional threshold skew value being associated with the additional particular signal frequency value according to the skew mask; and coupling a third electronic component and a fourth electronic component to one another using the additional cable in response to determining the additional measured skew value is below the additional threshold skew value.

In some aspects, the techniques described herein relate to a method including: determining a plurality of skew values of a plurality of cables, wherein each skew value of the plurality of skew values indicates a time of signal propagation along a respective cable of the plurality of cables at a respective signal frequency value of a plurality of signal frequency values, and the plurality of skew values varies at the plurality of signal frequency values; determining a plurality of skew behavior property values of the plurality of cables based on the plurality of skew values; determining a plurality of performance metric values based on the plurality of skew behavior property values of the plurality of cables; and modeling a respective skew mask associated with each performance metric value of the plurality of performance metric values based on the plurality of skew values of the plurality of cables and the plurality of performance metric values, wherein each respective skew mask defines a respective plurality of threshold skew values that achieves the performance metric value of the plurality of performance metric values associated with the respective skew mask at the plurality of signal frequency values to indicate manufacturability of a selected cable based on a skew value of the selected cable.

In some aspects, the techniques described herein relate to a method, wherein determining the plurality of performance metric values includes using a simulator to determine the plurality of performance metric values based on the plurality of skew behavior property values, wherein the simulator includes a runtime domain serializer/deserializer simulator, a serializer/deserializer channel simulator, a channel operating margin tool, or any combination thereof.

In some aspects, the techniques described herein relate to a method, wherein each respective skew mask includes a graphical plot that defines the respective plurality of threshold skew values that achieves the performance metric value of the plurality of performance metric values associated with the respective skew mask at the plurality of signal frequency values.

In some aspects, the techniques described herein relate to a method, wherein the plurality of performance metric values includes a bit error rate, a signal to noise ratio, and/or or a channel operating margin tool value for a simulated channel.

Note that in certain example implementations, operations as set forth herein may be implemented by logic encoded in one or more tangible media that is capable of storing instructions and/or digital information and may be inclusive of non-transitory tangible media and/or non-transitory computer readable storage media (e.g., embedded logic provided in: an ASIC, digital signal processing (DSP) instructions, software [potentially inclusive of object code and source code], etc.) for execution by one or more processor(s), and/or other similar machine, etc. Generally, the storage 1006 and/or memory elements(s) 1004 can store data, software, code, instructions (e.g., processor instructions), logic, parameters, combinations thereof, and/or the like used for operations described herein. This includes the storage 1006 and/or memory elements(s) 1004 being able to store data, software, code, instructions (e.g., processor instructions), logic, parameters, combinations thereof, or the like that are executed to carry out operations in accordance with teachings of the present disclosure.

In some instances, software of the present embodiments may be available via a non-transitory computer useable medium (e.g., magnetic or optical mediums, magneto-optic mediums, CD-ROM, DVD, memory devices, etc.) of a stationary or portable program product apparatus, downloadable file(s), file wrapper(s), object(s), package(s), container(s), and/or the like. In some instances, non-transitory computer readable storage media may also be removable. For example, a removable hard drive may be used for memory/storage in some implementations. Other examples may include optical and magnetic disks, thumb drives, and smart cards that can be inserted and/or otherwise connected to a computing device for transfer onto another computer readable storage medium.

To the extent that embodiments presented herein relate to the storage of data, the embodiments may employ any number of any conventional or other databases, data stores or storage structures (e.g., files, databases, data structures, data, or other repositories, etc.) to store information.

Note that in this Specification, references to various features (e.g., elements, structures, nodes, modules, components, engines, logic, steps, operations, functions, characteristics, etc.) included in ‘one embodiment’, ‘example embodiment’, ‘an embodiment’, ‘another embodiment’, ‘certain embodiments’, ‘some embodiments’, ‘various embodiments’, ‘other embodiments’, ‘alternative embodiment’, and the like are intended to mean that any such features are included in one or more embodiments of the present disclosure, but may or may not necessarily be combined in the same embodiments. Note also that a module, engine, client, controller, function, logic or the like as used herein in this Specification, can be inclusive of an executable file comprising instructions that can be understood and processed on a server, computer, processor, machine, compute node, combinations thereof, or the like and may further include library modules loaded during execution, object files, system files, hardware logic, software logic, or any other executable modules.

It is also noted that the operations and steps described with reference to the preceding figures illustrate only some of the possible scenarios that may be executed by one or more entities discussed herein. Some of these operations may be deleted or removed where appropriate, or these steps may be modified or changed considerably without departing from the scope of the presented concepts. In addition, the timing and sequence of these operations may be altered considerably and still achieve the results taught in this disclosure. The preceding operational flows have been offered for purposes of example and discussion. Substantial flexibility is provided by the embodiments in that any suitable arrangements, chronologies, configurations, and timing mechanisms may be provided without departing from the teachings of the discussed concepts.

As used herein, unless expressly stated to the contrary, use of the phrase ‘at least one of’, ‘one or more of’, ‘and/or’, variations thereof, or the like are open-ended expressions that are both conjunctive and disjunctive in operation for any and all possible combination of the associated listed items. For example, each of the expressions ‘at least one of X, Y and Z’, ‘at least one of X, Y or Z’, ‘one or more of X, Y and Z’, ‘one or more of X, Y or Z’ and ‘X, Y and/or Z’ can mean any of the following: 1) X, but not Y and not Z; 2) Y, but not X and not Z; 3) Z, but not X and not Y; 4) X and Y, but not Z; 5) X and Z, but not Y; 6) Y and Z, but not X; or 7) X, Y, and Z.

Additionally, unless expressly stated to the contrary, the terms ‘first’, ‘second’, ‘third’, etc., are intended to distinguish the particular nouns they modify (e.g., element, condition, node, module, activity, operation, etc.). Unless expressly stated to the contrary, the use of these terms is not intended to indicate any type of order, rank, importance, temporal sequence, or hierarchy of the modified noun. For example, ‘first X’ and ‘second X’ are intended to designate two ‘X’ elements that are not necessarily limited by any order, rank, importance, temporal sequence, or hierarchy of the two elements. Further as referred to herein, ‘at least one of’ and ‘one or more of can be represented using the’ (s)′ nomenclature (e.g., one or more element(s)).

Each example embodiment disclosed herein has been included to present one or more different features. However, all disclosed example embodiments are designed to work together as part of a single larger system or method. This disclosure explicitly envisions compound embodiments that combine multiple previously discussed features in different example embodiments into a single system or method.

One or more advantages described herein are not meant to suggest that any one of the embodiments described herein necessarily provides all of the described advantages or that all the embodiments of the present disclosure necessarily provide any one of the described advantages. Numerous other changes, substitutions, variations, alterations, and/or modifications may be ascertained to one skilled in the art and it is intended that the present disclosure encompass all such changes, substitutions, variations, alterations, and/or modifications as falling within the scope of the appended claims.

Further, the present disclosure may repeat reference numerals and/or letters in the various examples. This repetition is for the purpose of simplicity and clarity and does not in itself dictate a relationship between the various embodiments and/or configurations discussed. Example embodiments that may be used to implement the features and functionality of this disclosure are described with more particular reference to the accompanying figures above.

Similarly, when used herein, the term “comprises” and its derivations (such as “comprising”, etc.) should not be understood in an excluding sense, that is, these terms should not be interpreted as excluding the possibility that what is described and defined may include further elements, steps, etc. Meanwhile, when used herein, the term “approximately” and terms of its family (such as “approximate”, etc.) should be understood as indicating values very near to those which accompany the aforementioned term. That is to say, a deviation within reasonable limits from an exact value should be accepted, because a skilled person in the art will understand that such a deviation from the values indicated is inevitable due to measurement inaccuracies, etc. The same applies to the terms “about” and “around” and “substantially”.

What is claimed is:

1. A method comprising:
determining a plurality of skew values of a plurality of cables, wherein each skew value of the plurality of skew values indicates a time of signal propagation along a respective cable of the plurality of cables at a respective signal frequency value of a plurality of signal frequency values, and the plurality of skew values are frequency dependent and vary at the plurality of signal frequency values;
determining a plurality of skew behavior property values for each cable of the plurality of cables based on the plurality of skew values;
determining a performance metric value for each skew behavior property value of the plurality of skew behavior property values to generate a plurality of performance metric values;
determining a relationship between the plurality of skew values and the plurality of signal frequency values at each performance metric value of the plurality of performance metric values based on the performance metric value for each skew behavior property value; and
coupling a first electronic component and a second electronic component to one another using a new cable, separate from the plurality of cables, based on the relationship between the plurality of skew values and the plurality of signal frequency values at each performance metric value.

2. The method of claim 1, wherein coupling the first electronic component and the second electronic component to one another using the new cable based on the relationship between the plurality of skew values and the plurality of signal frequency values comprises at each performance metric value comprises:
determining a new skew value for the new cable at a selected signal frequency value of the plurality of signal frequency values;
determining a target performance metric value of the plurality of performance metric values;
comparing the new skew value to a selected skew value of the plurality of skew values based on the selected skew value corresponding to the selected signal frequency value according to the relationship between the plurality of skew values and the plurality of signal frequency values at the target performance metric value; and
coupling the first electronic component and the second electronic component to one another using the new cable based on the new skew value being below the selected skew value.

3. The method of claim 2, further comprising propagating signals through the new cable between the first electronic component and the second electronic component.

4. The method of claim 3, wherein at least one of the first electronic component or the second electronic component comprises a printed circuit board.

5. The method of claim 1, further comprising determining a selected skew profile from a plurality of skew profiles for each cable of the plurality of cables based on its plurality of skew values, wherein determining the relationship between the plurality of skew values and the plurality of signal frequency values at each performance metric value comprises determining a respective relationship between the plurality of skew values and the plurality of signal frequency values for each skew profile of the plurality of skew profiles at each performance metric value.

6. The method of claim 5, wherein coupling the first electronic component and the second electronic component to one another using the new cable comprises:
determining a new plurality of skew values of the new cable;
determining a skew profile of the plurality of skew profiles of the new cable based on the new plurality of skew values;
determining a new skew value of the new plurality of skew values of the new cable at a selected signal frequency value of the plurality of signal frequency values;
determining a target performance metric value of the plurality of performance metric values;
comparing the new skew value to a selected skew value of the plurality of skew values based on the selected skew value corresponding to the selected signal frequency value according to the respective relationship between the plurality of skew values and the plurality of signal frequency values for the skew profile of the new cable at the target performance metric value; and
coupling the first electronic component and the second electronic component to one another using the new cable based on the new skew value being below the selected skew value.

7. The method of claim 1, wherein determining the relationship between the plurality of skew values and the plurality of signal frequency values at each performance metric value comprises determining a respective relationship between the plurality of skew values and the plurality of signal frequency values for each data rate transmission of a plurality of data rate transmissions at each performance metric value.

8. The method of claim 7, wherein coupling the first electronic component and the second electronic component to one another using the new cable comprises:
determining a new plurality of skew values of the new cable;
determining a selected data rate transmission of the plurality of data rate transmissions;
determining a new skew value of the new plurality of skew values of the new cable at a selected signal frequency value of the plurality of signal frequency values;
determining a target performance metric value of the plurality of performance metric values;
comparing the new skew value to a selected skew value of the plurality of skew values based on the selected skew value corresponding to the selected signal frequency value according to the respective relationship between the plurality of skew values and the plurality of signal frequency values for the selected data rate transmission at the target performance metric value; and
coupling the first electronic component and the second electronic component to one another using the new cable based on the new skew value being below the selected skew value.

9. The method of claim 1, further comprising:
storing the relationship between the plurality of skew values and the plurality of signal frequency values at each performance metric value; and
retrieving the relationship between the plurality of skew values and the plurality of signal frequency values at each performance metric value from storage to couple the first electronic component and the second electronic component to one another using the new cable based on the relationship between the plurality of skew values and the plurality of signal frequency values at each performance metric value.

10. The method of claim 9, wherein the relationship between the plurality of skew values and the plurality of signal frequency values at each performance metric value is stored as one or more database tables.

11. A method comprising:
determining a measured skew value of a cable at a particular signal frequency value, wherein the measured skew value indicates a time of signal propagation along the cable and is frequency dependent;
selecting a target performance metric value;
selecting a skew mask from a plurality of skew masks based on the skew mask corresponding to the target performance metric value, wherein the skew mask associates a plurality of threshold skew values with respective, corresponding signal frequency values to achieve the target performance metric value;
identifying a threshold skew value of the plurality of threshold skew values based on the threshold skew value being associated with the particular signal frequency value according to the skew mask; and
coupling a first electronic component and a second electronic component to one another using the cable in response to determining the measured skew value is below the threshold skew value.

12. The method of claim 11, comprising:
determining an additional measured skew value of an additional cable at the particular signal frequency value; and
discarding the additional cable in response to determining the additional measured skew value is at or above the threshold skew value.

13. The method of claim 11, wherein each skew mask of the plurality of skew masks corresponds to a respective skew profile of a plurality of skew profiles, and wherein selecting the skew mask from the plurality of skew masks comprises:
determining a plurality of measured skew values of the cable at various signal frequency values, the plurality of measured skew values comprising the measured skew value, and the various signal frequency values comprising the particular signal frequency value;
selecting a selected skew profile from the plurality of skew profiles for the cable based on the plurality of measured skew values of the cable at the various signal frequency values; and
selecting the skew mask from the plurality of skew masks based on the skew mask corresponding to the target performance metric value and the selected skew profile.

14. The method of claim 11, wherein each skew mask of the plurality of skew masks corresponds to a respective data rate transmission of a plurality of data rate transmissions, and wherein selecting the skew mask from the plurality of skew masks comprises:
determining a selected data rate transmission of the plurality of data rate transmissions for the cable; and
selecting the skew mask from the plurality of skew masks based on the skew mask corresponding to the target performance metric value and the selected data rate transmission.

15. The method of claim 11, further comprising:
determining an additional measured skew value of an additional cable at the particular signal frequency value;
selecting an additional target performance metric value;
selecting an additional skew mask from the plurality of skew masks based on the additional skew mask corresponding to the additional target performance metric value, wherein the additional skew mask associates an additional plurality of threshold skew values with additional, respective, corresponding signal frequency values to achieve the additional target performance metric value;
identifying an additional threshold skew value of the additional plurality of threshold skew values based on the additional threshold skew value being associated with the particular signal frequency value according to the additional skew mask; and
coupling a third electronic component and a fourth electronic component to one another using the additional cable in response to determining the additional measured skew value is below the additional threshold skew value.

16. The method of claim 11, further comprising:
determining an additional measured skew value of an additional cable at an additional particular signal frequency value;
identifying an additional threshold skew value of the plurality of threshold skew values based on the additional threshold skew value being associated with the additional particular signal frequency value according to the skew mask; and
coupling a third electronic component and a fourth electronic component to one another using the additional cable in response to determining the additional measured skew value is below the additional threshold skew value.

17. A method comprising:
determining a plurality of skew values of a plurality of cables, wherein each skew value of the plurality of skew values indicates a time of signal propagation along a respective cable of the plurality of cables at a respective signal frequency value of a plurality of signal frequency values, and the plurality of skew values varies at the plurality of signal frequency values;
determining a plurality of skew behavior property values of the plurality of cables based on the plurality of skew values;
determining a plurality of performance metric values based on the plurality of skew behavior property values of the plurality of cables; and
modeling a respective skew mask associated with each performance metric value of the plurality of performance metric values based on the plurality of skew values of the plurality of cables and the plurality of performance metric values, wherein each respective skew mask defines a respective plurality of threshold skew values that achieves the performance metric value of the plurality of performance metric values associated with the respective skew mask at the plurality of signal frequency values to indicate manufacturability of a selected cable based on a skew value of the selected cable.

18. The method of claim 17, wherein determining the plurality of performance metric values comprises using a simulator to determine the plurality of performance metric values based on the plurality of skew behavior property values, wherein the simulator comprises a runtime domain serializer/deserializer simulator, a serializer/deserializer channel simulator, a channel operating margin tool, or any combination thereof.

19. The method of claim 17, wherein each respective skew mask comprises a graphical plot that defines the respective plurality of threshold skew values that achieves the performance metric value of the plurality of performance metric values associated with the respective skew mask at the plurality of signal frequency values.

20. The method of claim 17, wherein the plurality of performance metric values comprises a bit error rate, a signal to noise ratio, and/or or a channel operating margin tool value for a simulated channel.
